(19) United States
(12) Patent Application Publication
(10) Pub. No.: US 2024/0280855 A1
(43) Pub. Date: Aug. 22, 2024

(54) BACKLIGHT MODULE AND MANUFACTURING METHOD THEREOF

(71) Applicant: CARUX TECHNOLOGY PTE. LTD., SINGAPORE (SG)

(72) Inventors: Chao-Sen Yang, Tainan (TW); Chueh-Yuan Nien, Tainan (TW); Chao-Chin Sung, Tainan (TW); Chien-Tzu Chu, Tainan (TW)

(73) Assignee: CARUX TECHNOLOGY PTE. LTD., SINGAPORE (SG)

(21) Appl. No.: 18/409,797

(22) Filed: Jan. 11, 2024

(30) Foreign Application Priority Data
Feb. 17, 2023 (CN) 202310131336.0

(51) Int. Cl. G02F 1/13357; G02F 1/1335; H01L 33/62

(52) U.S. Cl. CPC G02F 1/133603; G02F 1/133612; H01L 33/62; H01L 2933/0066

(57) ABSTRACT

A backlight module and a manufacturing method thereof are disclosed. The backlight module includes a substrate, a light emitting element, and a conductive layer. The substrate includes a central region and a peripheral region. The peripheral region surrounds the central region. The light emitting element is disposed in the central region. The conductive layer is disposed in the peripheral region and electrically connected to the light emitting element. The conductive layer has a first portion and a second portion. The first portion is closer to the light emitting element than the second portion. The first portion has a first metal layer area, and the second portion has a second metal layer area. The first metal layer area is greater than the second metal layer area. The backlight module and the manufacturing method thereof may reduce a loss of laser energy or improve a cutting yield during a cutting step of a manufacturing process.

### CROSS-REFERENCE TO RELATED APPLICATION

This application claims the priority benefit of China application serial no. 202310131336.0, filed on Feb. 17, 2023. The entirety of the above-mentioned patent application is hereby incorporated by reference herein and made a part of this specification.

### BACKGROUND

### Technical Field

The disclosure relates to a backlight module and a manufacturing method thereof, and more particularly, to a backlight module and a manufacturing method thereof which may reduce loss of laser energy or improve a cutting yield during a cutting step of a manufacturing process.

### Description of Related Art

Electronic devices or spliced electronic devices have been widely used in different fields such as communication, display, vehicle, or aviation. With the vigorous development of the electronic devices, the electronic devices are developed towards thinner and lighter. Therefore, requirements for reliability or quality of the electronic devices are higher.

### SUMMARY

The disclosure provides a backlight module and a manufacturing method thereof, which may reduce a loss of laser energy or improve a cutting yield during a cutting step of a manufacturing process.

According to an embodiment of the disclosure, a backlight module includes a substrate, a light emitting element, and a conductive layer. The substrate includes a central region and a peripheral region. The peripheral region surrounds the central region. The light emitting element is disposed in the central region. The conductive layer is disposed in the peripheral region and electrically connected to the light emitting element. The conductive layer has a first portion and a second portion. The first portion is closer to the light emitting element than the second portion. The first portion has a first metal layer area, and the second portion has a second metal layer area. The first metal layer area is greater than the second metal layer area.

According to an embodiment of the disclosure, a manufacturing method of a backlight module includes the following. A substrate is provided. The substrate includes a central region, a peripheral region, and a region to be cut. The peripheral region surrounds the central region, and the region to be cut surrounds the peripheral region. A light emitting element is disposed in the central region. A first conductive layer is formed in the peripheral region and the region to be cut to be electrically connected to the light emitting element. Through a cutting step, the first conductive layer located in the region to be cut is removed to obtain a second conductive layer. The second conductive layer has a first portion and a second portion. The first portion is closer to the light emitting element than the second portion. The first portion has a first metal layer area, and the second portion has a second metal layer area. The first metal layer area is greater than the second metal layer area.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a schematic top view of a backlight module before a cutting step according to an embodiment of the disclosure.

FIG. 1B is a schematic top view of the backlight module in FIG. 1A after the cutting step.

FIG. 2A is a schematic enlarged view of a region R1 in FIG. 1A.

FIG. 2B is a schematic enlarged view of a region R2 in FIG. 1B.

FIG. 3 is a schematic cross-sectional view of FIG. 2B taken along a section line I-I′.

FIG. 4 is a schematic enlarged view of the region R2 of the backlight module according to another embodiment in FIG. 2B.

FIG. 5 is a schematic enlarged view of the region R2 of the backlight module according to another embodiment in FIG. 2B.

FIG. 6 is a schematic cross-sectional view of a backlight module taken along the section line I-I′ according to another embodiment in FIG. 3.

FIG. 7 is a schematic cross-sectional view of a backlight module taken along the section line I-I′ according to another embodiment in FIG. 3.

FIG. 8 is a schematic cross-sectional view of a backlight module taken along the section line I-I′ according to another embodiment in FIG. 3.

### DETAILED DESCRIPTION OF DISCLOSED EMBODIMENTS

The disclosure can be understood by referring to the following detailed description in combination with the accompanying drawings. It should be noted that in order to make it easy for the reader to understand and for the simplicity of the drawings, the multiple drawings in this disclosure only depict a part of the electronic device, and the specific components in the drawings are not drawn according to actual scale. In addition, the number and size of each component in the drawings are only for exemplary purpose, and are not intended to limit the scope of the disclosure.

In the following description and claims, the terms “contain” and “include” are open-ended terms, so they should be interpreted as “include but not limited to . . . ”.

It should be understood that when an element or a film layer is referred to as being “on” or “connected to” another element or film layer, it can be directly on the another element or film layer or be directly connected to the another element or film layer, or an inserted element or film layer may be provided therebetween (not a direct connection). In contrast, when the element is referred to as being “directly on” another element or film layer or “directly connected to” another element or film layer, an inserted element or film layer is not provided therebetween.

Although the terms “first”, “second”, “third” . . . may be used to describe various constituent elements, the constituent elements are not limited to these terms. These terms are only used to distinguish a single constituent element from other constituent elements in the specification. The same terms may not be used in the claims, and the elements in the claims may be replaced with first, second, third . . . according to the order declared by the elements in the claims. Therefore, in the following description, the first constituent element may be the second constituent element in the claims.

In the text, the terms “about”, “approximately”, “substantially”, and “roughly” usually mean within 10%, 5%, 3%, 2%, 1%, or 0.5% of a given value or range. The number given here is an approximate number, that is, the meanings of “about”, “approximately”, “substantially”, and “roughly” may still be implied without specifying “about”, “approximately”, “substantially”, and “roughly”.

In some embodiments of the disclosure, regarding the words such as “connected”, “interconnected”, etc. referring to bonding and connection, unless specifically defined, these words mean that two structures are in direct contact or two structures are not in direct contact, and other structures are provided to be disposed between the two structures. The word for joining and connecting may also include the case where both structures are movable or both structures are fixed. In addition, the word “coupled” may include any direct or indirect electrical connection means.

In some embodiments of the disclosure, an optical microscopy (OM), a scanning electron microscope (SEM), a film thickness profile measuring instrument (α-step), an elliptical thickness measuring instrument, or other suitable methods may be adopted to measure the area, width, thickness, or height of each element or to measure the distance or spacing between elements. In detail, according to some embodiments, the scanning electron microscope may be used to obtain a cross-sectional structural image of an element to be measured, and to measure the area, width, thickness, or height of each element, or the distance or spacing between elements.

A backlight module in the disclosure may be applied to the electronic device. The electronic device may include a display device, an antenna device, a sensing device, or a splicing device, but the disclosure is not limited thereto. The electronic device may be a bendable or flexible electronic device. The electronic device may, for example, include a liquid crystal light emitting diode. The light emitting diode may, for example, include an organic light emitting diode (OLED), a mini light emitting diode (mini LED), a micro light emitting diode (micro LED), or a quantum dot light emitting diode (QD, which may be, for example, QLED or QDLED), fluorescence, phosphor, or other suitable materials, and the materials thereof may be arranged in any combination. However, the disclosure is not limited thereto. The antenna device may be, for example, a liquid crystal antenna, but the disclosure is not limited thereto. The splicing device may be, for example, a display splicing device or an antenna splicing device, but the disclosure is not limited thereto. Note that the electronic device may be any combination of the foregoing, but the disclosure is not limited thereto. Hereinafter, the disclosure is described with the backlight module in the electronic device, but the disclosure is not limited thereto.

It should be understood that in the following embodiments, the features of several different embodiments may be replaced, recombined, and mixed to complete other embodiments without departing from the spirit of the disclosure. As long as the features of the embodiments do not violate or do not conflict with the spirit of the disclosure, they may be mixed and matched arbitrarily.

Reference will now be made in detail to the exemplary embodiments of the disclosure, and examples of the exemplary embodiments are illustrated in the accompanying drawings. Whenever possible, the same reference numerals are used in the drawings and descriptions to indicate the same or similar parts.

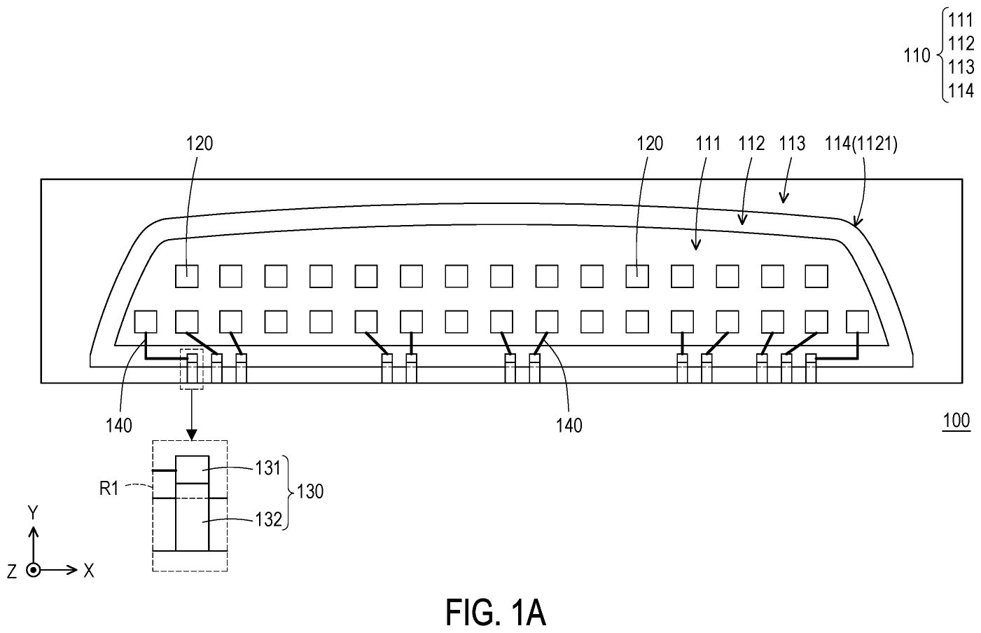

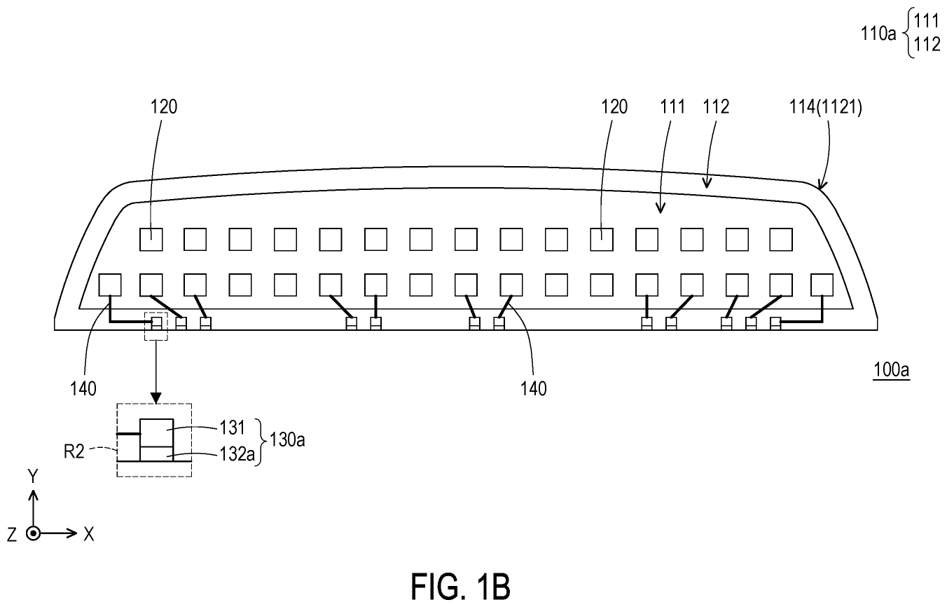

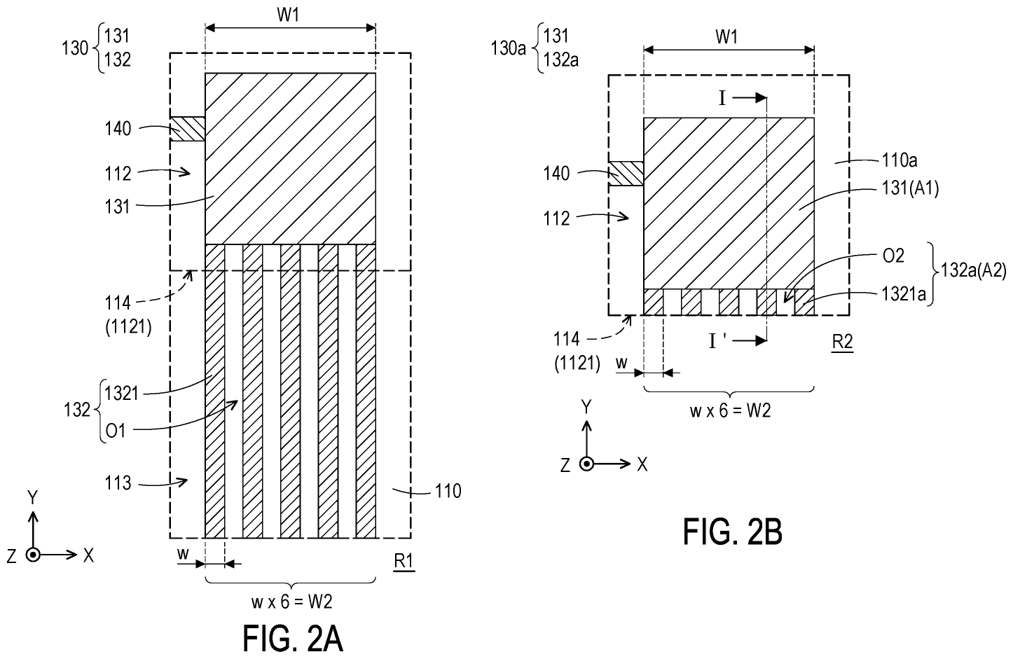

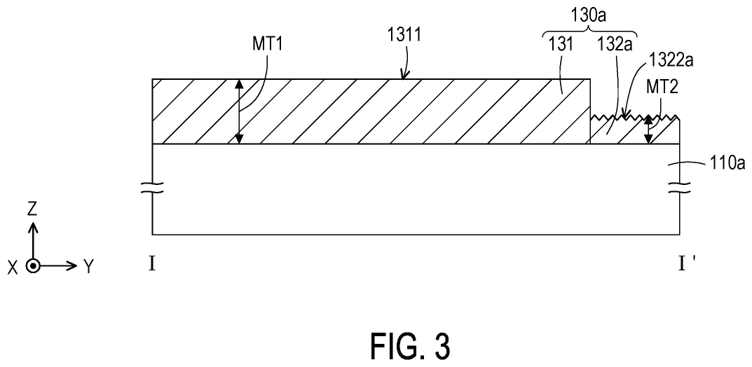

FIG. 1A is a schematic top view of a backlight module before a cutting step according to an embodiment of the disclosure. FIG. 1B is a schematic top view of the backlight module in FIG. 1A after the cutting step. FIG. 2A is a schematic enlarged view of a region R1 in FIG. 1A. FIG. 2B is a schematic enlarged view of a region R2 in FIG. 1B. FIG. 3 is a schematic cross-sectional view of FIG. 2B taken along a section line I-I′.

Referring to FIG. 1A, FIG. 1A shows a backlight module 100 before the cutting step in this embodiment. In this embodiment, the backlight module 100 before the cutting step may include a substrate 110, a light emitting element 120, a conductive layer 130, and a driving circuit 140. The substrate 110 includes a central region 111, a peripheral region 112, a region 113 to be cut, and a cutting line 114. The peripheral region 112 surrounds the central area 111. The region 113 to be cut surrounds the peripheral region 112. The peripheral region 112 is disposed between the central region 111 and the region 113 to be cut. The cutting line 114 is disposed at a junction (i.e., an edge 1121 of the peripheral region 112) between the peripheral region 112 and the region 113 to be cut. The region 113 to be cut may be removed in the subsequent cutting step. The cutting step may be, for example, using laser cutting, so that the laser cuts along the cutting line 114 to remove the region 113 to be cut and a portion of the conductive layer 130 located in the region 113 to be cut, but the disclosure is not limited thereto. For example, the backlight module 100 is formed by special-shaped cutting technology, but the disclosure is not limited thereto.

Referring to FIG. 1B, FIG. 1B shows a backlight module 100a after the cutting step in this embodiment. In this embodiment, the backlight module 100a after the cutting step includes a substrate 110a, the light emitting element 120, a conductive layer 130a, and the driving circuit 140. The substrate 110a includes the central region 111 and the peripheral region 112, and the peripheral region 112 surrounds the central region 111. In this embodiment, the substrate 110a may include a rigid substrate, a flexible substrate, or a combination of the foregoing. For example, a material of the substrate 110a may include glass, quartz, sapphire, ceramics, polycarbonate (PC), polyimide (PI), polyethylene terephthalate (PET), epoxy glass fiber, flame resistant glass fiber (FR4), other suitable substrate materials, or a combination of the foregoing, but the disclosure is not limited thereto.

Referring to both FIG. 1A and FIG. 1B, the light emitting element 120 is disposed on the substrate 110 (or the substrate 110a), and the light emitting element 120 may be disposed in the central region 111. The light emitting element 120 may include a light emitting diode. For example, the light emitting element 120 may include a red light emitting diode, a green light emitting diode, a blue light emitting diode and/or a white light emitting diode, an organic light emitting diode (OLED), a mini light emitting diode (mini LED), a micro light emitting diode (micro LED) or a quantum dot light emitting diode (QD, which may be, for example, QLED or QDLED), fluorescence, phosphor, or other suitable materials, and the materials thereof may be arranged in any combination. However, the disclosure is not limited thereof.

Referring to FIG. 1A, FIG. 1B, FIG. 2A, and FIG. 2B, FIG. 2A is an enlarged view of the conductive layer 130, and FIG. 2B is an enlarged view of the conductive layer 130a. In addition, the conductive layer 130a in FIG. 2B is the conductive layer after the conductive layer 130 in FIG. 2A is cut along the cutting line 114. In this embodiment, the conductive layer 130 is disposed on the substrate 110, and the conductive layer 130a is disposed on the substrate 110a. The conductive layer 130 (or the conductive layer 130a) may be electrically connected to the light emitting element 120 through the driving circuit 140. In this embodiment, a material of the conductive layer 130 (or the conductive layer 130a) may include one of materials such as copper, indium tin oxide (ITO), titanium/aluminum/titanium, a combination thereof or a material stack thereof, one of materials such as molybdenum/aluminum/molybdenum, a combination thereof or a material stack thereof, other suitable conductive materials, or a combination of the foregoing, but the disclosure is not limited thereto.

Specifically, continuing to refer to FIG. 1A and FIG. 2A, the conductive layer 130 is disposed in the peripheral region 112 and the region 113 to be cut. The conductive layer 130 has a first portion 131 and a second portion 132. The first portion 131 is disposed in the peripheral region 112, and the second portion 132 is connected to the first portion 131 and extends to the region 113 to be cut. The second portion 132 has multiple sub-portions 1321 and multiple openings O1. The sub-portions 1321 are separated from one another. The openings O1 may separate the sub-portions 1321 in an X direction, and may expose a portion of the substrate 110. The cutting line 114 passes through the second portion 132. That is, in a top view, the cutting line 114 overlaps the sub-portions 1321 and the openings O1.

Continuing to refer to FIG. 1B and FIG. 2B, the conductive layer 130a is disposed in the peripheral region 112. The conductive layer 130a has the first portion 131 and a second portion 132a, and the first portion 131 is connected to the second portion 132a. In a Y direction, the first portion 131 is closer to the light emitting element 120 than the second portion 132a, and the second portion 132a is closer to the edge 1121 of the peripheral region 112 than the first portion 131. The second portion 132a has multiple sub-portions 1321a and multiple openings O2. The sub-portions 1321a are separated from one another. The openings O2 may separate the sub-portions 1321a, and may expose a portion of the substrate 110a.

In manufacturing of the general backlight module, when the laser is used to perform the cutting step on the substrate, the laser will be reflected by the conductive layer, resulting in reduced laser energy or poor cutting (for example, the substrate is not cut, or the substrate is broken, etc.). However, the second portion 132 of the conductive layer 130 (or the second portion 132a of the conductive layer 130a) in this embodiment has the openings O1 (or the openings O2) that may overlap the cutting line 114. Therefore, during a cutting step of a manufacturing process, the backlight module 100a in this embodiment may reduce the reflection of the laser by reducing a path of the laser passing through the conductive layer, thereby reducing a loss of laser energy or improving a cutting yield.

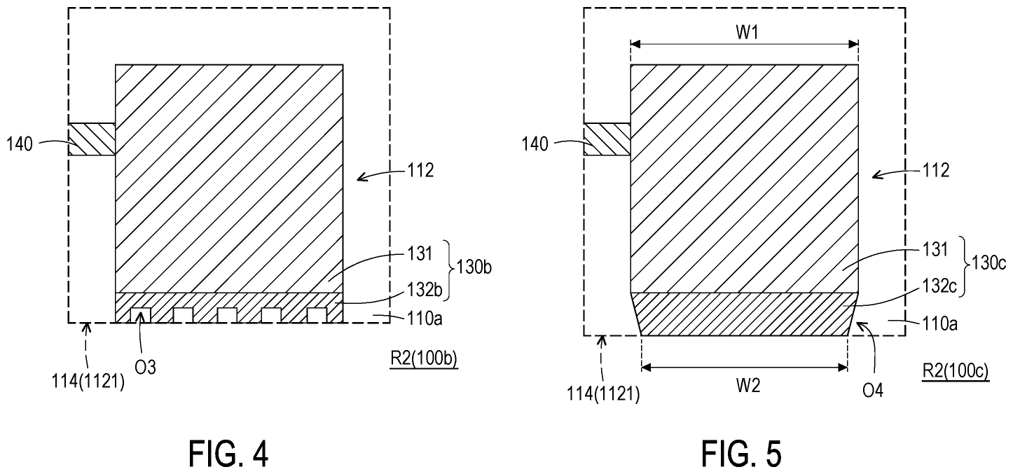

In this embodiment, shapes of the sub-portion 1321 and the sub-portion 1321a may be, for example, a rectangle, and shapes of the opening O1 and the opening O2 may be, for example, a rectangle. However, the disclosure is not limited thereto. In some embodiments, a shape of the second portion 132 may also be comb-like (as shown in FIG. 4), trapezoidal (as shown in FIG. 5), U-shaped, or a combination of the foregoing, as long as a minimum width of the second portion is less than a width of the first portion. In some embodiments, the shape of the opening (O1, O2, O3, and O4) may also be a triangle (as shown in FIG. 5), a parallelogram, a semicircle, an arc, a circle, a rhombus, a lightning bolt, or a combination of the foregoing, as long as the opening of the second portion may expose a portion of the substrate.

In this embodiment, the first portion 131 of the conductive layer 130a has a first metal layer area A1, and the second portion 132a of the conductive layer 130a has a second metal layer area A2. The metal layer areas A1 and A2 may be, for example, the metal layer areas on an X-Y plane, and the first metal layer area A1 may, for example, be greater than the second metal layer area A2 (i.e., A1>A2), but the disclosure is not limited thereto. The metal layer area may be calculated and compared using, for example, an integral area, but the disclosure is not limited thereto.

In this embodiment, a first direction X, a second direction Y, and a third direction Z are different directions respectively. The second direction Y is, for example, an arrangement direction of the first portion 131 and the second portion 132 (or the second portion 132a), and the third direction Z is, for example, is a normal direction of the substrate 110 (or the substrate 110a). The first direction X is substantially perpendicular to the second direction Y and the third direction Z respectively, and the second direction Y is substantially perpendicular to the third direction Z.

In this embodiment, the first portion 131 has a minimum width W1, and the second portion 132 (or the second portion 132a) has a minimum width W2 (i.e., a sum of minimum widths W of all the sub-portions 1321 (or the sub-portions 1321a)). The minimum width W may be, for example, less than the minimum width W1 (i.e., W<W1), and the minimum width W2 may be, for example, less than the minimum width W1 (i.e., W2<W1), but the disclosure is not limited thereto. The minimum width W is, for example, the minimum width of the sub-portion 1321 (or the sub-portion 1321a) measured along the first direction X. The minimum width W1 is, for example, the minimum width of the first portion 131 measured along the first direction X. The minimum width W2 is, for example, the minimum width of the second portion 132 (or the second portion 132a) measured along the first direction X. Compared to a situation in which the general backlight module will be reflected because the laser passes through the conductive layer when using the laser for the cutting step, resulting in the reduced laser energy or poor cutting, since the minimum width W2 of the second portion 132 of the conductive layer 130 (or the second portion 132a of the conductive layer 130a) in this embodiment may be less than the minimum width W1 of the first portion 131, in the cutting step of the manufacturing process, the backlight module 100a in this embodiment may reduce the reflection of the laser by reducing the path of the laser passing through the conductive layer, thereby reducing the loss of laser energy or improving the cutting yield.

In this embodiment, the conductive layer 130 (or the conductive layer 130a) may be used for electrical testing, for example, for testing whether there is a good electrical connection between the driving circuit 140 and the light emitting element 120, or for testing whether the light emitting element 120 may emit light, but the disclosure is not limited thereto. The first portion 131 of the conductive layer 130 (or the conductive layer 130a) may be, for example, a test pad, and the second portion 132 (or the second portion 132a) may be, for example, a metal trace. However, the disclosure is not limited thereto. In some embodiments, the first portion may include the test pad and a portion of the metal trace, and the second portion may include another portion of the metal trace. In some embodiments, the first portion may include a portion of the test pad, and the second portion may include another portion of the test pad and the metal trace.

Referring to FIG. 3 (i.e., a cross-sectional view of FIG. 2B), the first portion 131 of the conductive layer 130a has a first metal layer thickness MT1, and the second portion 132a of the conductive layer 130a has a second metal layer thickness MT2. The second metal layer thickness MT2 may be, for example, less than the first metal layer thickness MT1 (i.e., MT2<MT1), but the disclosure is not limited thereto. The first metal layer thickness MTI is, for example, the thickness of the first portion 131 measured along the third direction Z. The second metal layer thickness MT2 is, for example, the thickness of the second portion 132a measured along the third direction Z. In this embodiment, the first metal layer thickness MT1 of the first portion 131 of the conductive layer 130a may be, for example, 300 nanometers (nm) to 600 nm, 600 nm to 1000 nm, 1000 nm to 1500 nm, 1500 nm to 2000 nm, etc., and the second metal layer thickness MT2 of the second portion 132a may be, for example, 100 nm to 300 nm. However, the disclosure is not limited thereto. In addition, compared to a situation in which during the manufacturing of the general backlight module, when the laser is used for the cutting step, the general backlight module will be reflected because the laser passes through the conductive layer, resulting in the reduced laser energy or poor cutting, since the second metal layer thickness MT2 of the second portion 132 of the conductive layer 130 (or the second portion 132a of the conductive layer 130a) in this embodiment may be less than the first metal layer thickness MT1 of the first portion 131, the backlight module 100a in this embodiment may reduce the reflection of the laser in the cutting step of the manufacturing process, thereby reducing the loss of laser energy or improving the cutting yield.

In this embodiment, roughness of a surface 1322a of the second portion 132a of the conductive layer 130a away from the substrate 110 after laser cutting may be greater than roughness of a surface 1311 of the first portion 131 away from the substrate 110, but the disclosure is not limited thereto. The roughness may be measured or compared by means of probe, optical, microscope observation, etc., but the disclosure is not limited thereto.

Referring to FIG. 1A, FIG. 1B, FIG. 2A, and FIG. 2B again, the driving circuit 140 is disposed on the substrate 110 (or the substrate 110a). The driving circuit 140 may be disposed in the central region 111 and the peripheral region 112 , and the driving circuit 140 may be electrically connected to the light emitting element 120 disposed in the central region 111 and the conductive layer 130 (or the conductive layer 130a) disposed in the peripheral region 112. The driving circuit 140 may include the metal trace, a driving chip (not shown), etc., but the disclosure is not limited thereto.

In this embodiment, a manufacturing method of the backlight module 100 and the backlight module 100a may, for example, include but is not limited to the following steps. First, the substrate 110 is provided. The substrate 110 includes the central region 111, the peripheral region 112, the region 113 to be cut, and the cutting line 114. The peripheral region 112 surrounds the central region 111. The region 113 to be cut surrounds the peripheral region 112. The cutting line 114 is disposed at the junction between the peripheral region 112 and the region 113 to be cut. Next, the light emitting element 120 is disposed in the central region 111. Then, the first conductive layer 130 is formed in the peripheral region 112 and the region 113 to be cut, so that the conductive layer 130 may be electrically connected to the light emitting element 120, and the backlight module 100 is obtained. Through the cutting step, the region 113 to be cut is removed to obtain the substrate 110a, the second conductive layer 130a, and the backlight module 100a. The substrate 110a includes the central region 111 and the peripheral region 112. The second conductive layer 130a is disposed in the peripheral region 112. The second conductive layer 130a has the first portion 131 and the second portion 132a, and the first portion 131 is closer to the light emitting element 120 than the second portion 132a. The first portion 131 has the first metal layer area A1, and the second portion 132a has the second metal layer area A2. The first metal layer area A1 is greater than the second metal layer area A2.

In this embodiment, a method of forming the first conductive layer 130 includes but is not limited to the following steps. First, a first metal layer (not shown) is formed in the peripheral region 112 and the region 113 to be cut by sputtering, for example. Next, for example, the second portion 132 of the conductive layer 130 is patterned by photolithography to form the first conductive layer 130. Then, the cutting step is performed. For example, the substrate and the metal layer located in the region 113 to be cut are removed by laser cutting along the cutting line 114 to form the second conductive layer 130a.

Some other embodiments are provided below to describe the disclosure. It is noted that some of the reference numerals and descriptions of the above embodiment will apply to the following embodiments. The same reference numerals will represent the same or similar components and the descriptions of the same technical contents will be omitted. Reference may be made to the above embodiment for the omitted descriptions, which will not be repeated in the following embodiments.

FIG. 4 is a schematic enlarged view of the region R2 of the backlight module according to another embodiment in FIG. 2B. Referring to both FIG. 2B and FIG. 4, a backlight module 100b in this embodiment is similar to the backlight module 100a in FIG. 2B. A difference between the two is that in the backlight module 100b in this embodiment, a shape of a second portion 132b of a conductive layer 130b is comb-like.

Specifically, referring to FIG. 4, in this embodiment, the conductive layer 130b has the first portion 131 and the second portion 132b. The second portion 132b has multiple openings O3. The openings O3 may expose the portion of the substrate 110a, but not a portion of the first portion 131. A shape of the openings O3 is a rectangle.

FIG. 5 is a schematic enlarged view of the region R2 of the backlight module according to another embodiment in FIG. 2B. Referring to both FIG. 2B and FIG. 5, a backlight module 100c in this embodiment is similar to the backlight module 100a in FIG. 2B. A difference between the two is that in the backlight module 100c in this embodiment, a shape of a second portion 132c of a conductive layer 130c is trapezoidal.

Specifically, referring to FIG. 5, in this embodiment, the conductive layer 130c has the first portion 131 and the second portion 132c. The second portion 132c has multiple openings O4. The openings O4 may expose the portion of the substrate 110a, but not the portion of the first portion 131. A shape of the openings O4 is a triangle.

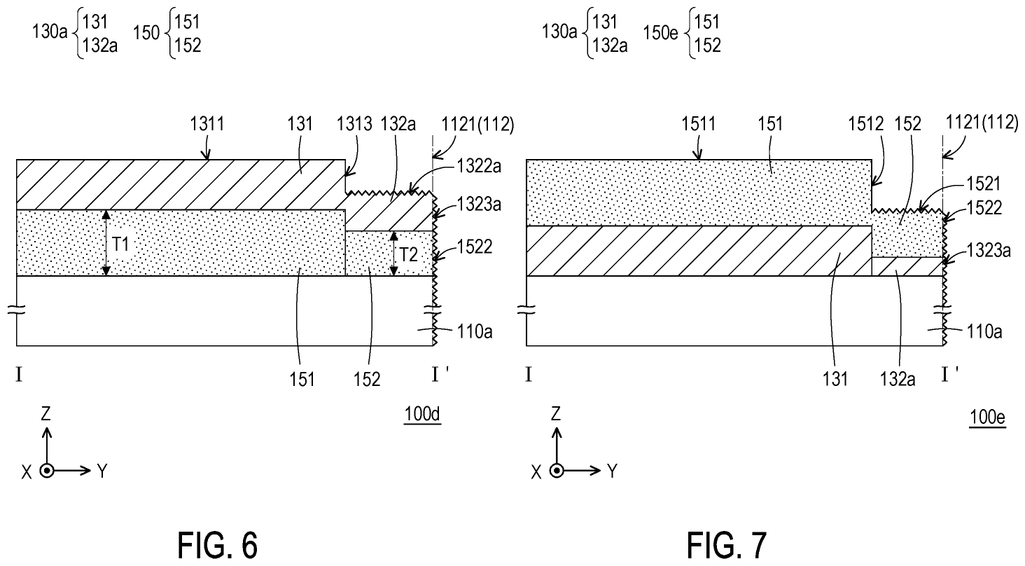

FIG. 6 is a schematic cross-sectional view of a backlight module taken along the section line I-I′ according to another embodiment in FIG. 3. Referring to both FIG. 3 and FIG. 6, a backlight module 100d in this embodiment is similar to the backlight module 100a in FIG. 3. A difference between the two is that the backlight module 100d in this embodiment further includes a first insulation layer 150.

Specifically, referring to FIG. 6, the first insulation layer 150 is disposed on the substrate 110a, and is disposed between the substrate 110a and the conductive layer 130a. In this embodiment, the first insulation layer 150 includes a first region 151 and a second region 152. The first region 151 corresponds to the first portion 131 of the conductive layer 130a, and the second region 152 corresponds to the second region 132a of the conductive layer 130a. In the third direction Z, the first region 151 overlaps the first portion 131 of the conductive layer 130a, and the second region 152 overlaps the second portion 132a of the conductive layer 130a.

In this embodiment, the first region 151 has a thickness T1, and the second region 152 has a thickness T2. The thickness T2 of the second region 152 may be, for example, less than the thickness T1 of the first region 151 (i.e., T2<T1), but the disclosure is not limited thereto. The thickness T1 is, for example, the thickness of the first region 151 measured along the third direction Z, and the thickness T2 is, for example, the thickness of the second region 152 measured along the third direction Z. In this embodiment, the thickness T1 of the first region 151 of the first insulation layer 150 may be, for example, 600 nm to 1000 nm, 1000 nm to 1500 nm, 1500 nm to 2000 nm, etc., and the thickness T2 of the second region 152 may be, for example, 0 nm to 600 nm. However, the disclosure is not limited thereto. In this embodiment, the first insulation layer 150 may be a single-layer structure or a multi-layer structure, and a material of the first insulation layer 150 may include an organic material, an inorganic material or a combination of the foregoing. However, the disclosure is not limited thereto. In addition, compared to a situation in which in the manufacturing process of the general backlight module, when the laser is used for the cutting step, it will be absorbed because the laser passes through the insulation layer, resulting in the reduced laser energy or poor cutting, since the thickness T2 of the second region 152 of the first insulation layer 150 in this embodiment may be less than the thickness T1 of the first region 151, the backlight module 100d in this embodiment may reduce the laser absorption during the cutting step of the manufacturing process, thereby reducing the loss of laser energy or improving the cutting yield.

In this embodiment, a manufacturing method of the backlight module 100d further includes the following. The first insulation layer 150 is formed between the substrate 110 and the conductive layer 130 (or the conductive layer 130a). A method of forming the first insulation layer 150 includes but is not limited to the following steps. First, a photoresist layer is formed in a portion corresponding to the peripheral region 112 and in the region 113 to be cut, and then, for example, the peripheral region 112 and the region 113 to be cut of the first insulation material on the substrate 110 are formed by chemical vapor deposition (CVD). Next, the photoresist layer is removed. At this time, when the photoresist layer is removed, the portion corresponding to the peripheral region 112 and the first insulation material located in the region 113 to be cut are removed. Then, for example, a second insulation material (not shown) is formed in the peripheral region 112 and the region 113 to be cut by the chemical vapor deposition. In this way, the first region 151 of the first insulation layer 150 includes a first insulation material and a second insulation material, a second region 152 of the insulation layer 150 includes the second insulation material. Therefore, the thickness of the first region 151 of the first insulation layer 150 is also greater than the thickness of the second region 152. The first region 151 may correspond to the first portion 131 of the second conductive layer 130a, and the second region 152 may correspond to the second portion 132a of the second conductive layer 130a. The conductive layer 130 is formed on the first insulation layer 150, and may be directly formed by, for example, sputtering, or the photoresist layer may be formed in the portion corresponding to the peripheral region 112 and in the region 113 to be cut, and then peripheral region 112 and the region 113 to be cut of a first conductive material on the substrate 110 are formed by sputtering. Then, the peripheral region 112 and the region 113 to be cut of a second conductive material on the substrate 110 are formed by sputtering.

In this embodiment, the roughness of the surface 1322a of the second portion 132a of the conductive layer 130a after laser cutting may be greater than the roughness of the surface 1311 of the first portion 131, but the disclosure is not limited thereto. In another embodiment, roughness of a side surface 1323a of the second portion 132a of the conductive layer 130a adjacent to the edge 1121 of the peripheral region 112 may be, for example, greater than that of a side surface 1313 of the first portion 131 adjacent to the edge 1121 of the peripheral region 112, but the disclosure is not limited thereto.

FIG. 7 is a schematic cross-sectional view of a backlight module taken along the section line I-I′ according to another embodiment in FIG. 3. Referring to both FIG. 6 and FIG. 7, a backlight module 100e in this embodiment is similar to the backlight module 100d in FIG. 6. A difference between the two is that in the backlight module 100e in this embodiment, a first insulation layer 150e is disposed on the conductive layer 130a, so that the conductive layer 130a is located between the first insulation layer 150e and the substrate 110a. That is to say, an order of the manufacturing method is changed from first forming the first insulation layer 150 on the substrate 110 and then forming the first conductive layer 130 described in FIG. 6 to first forming the first conductive layer 130 on the substrate 110 and then forming the first insulation layer 150. In this embodiment, roughness of a surface 1521 of the second region 152 of the first insulation layer 150e after laser cutting may be greater than roughness of a surface 1511 of the first region 151, but the disclosure is not limited thereto. In another embodiment, roughness of a side surface 1522 of the second region 152 of the first insulation layer 150 adjacent to the edge 1121 of the peripheral region 112 may be greater than that of a side surface 1512 of the first region 151 adjacent to the edge 1121 of the peripheral region 112, but the disclosure is not limited thereto.

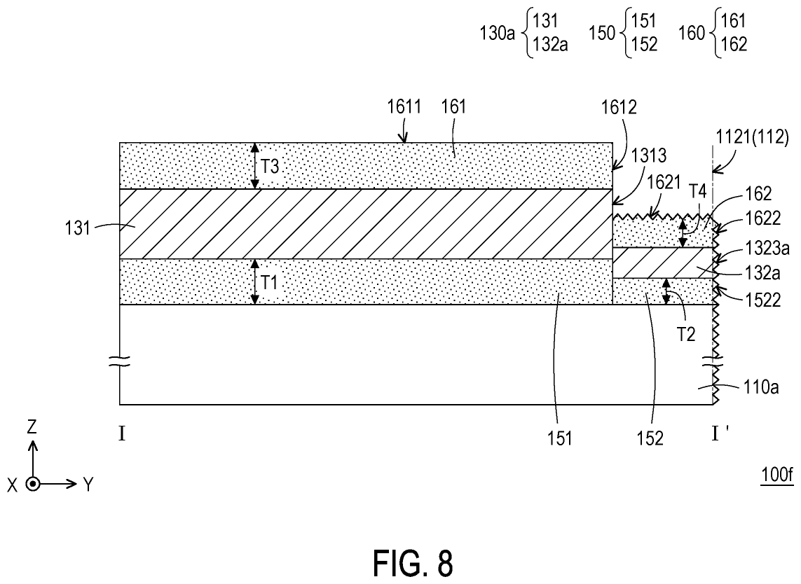

FIG. 8 is a schematic cross-sectional view of a backlight module taken along the section line I-I′ according to another embodiment in FIG. 3. Referring to both FIG. 6 and FIG. 8, a backlight module 100f in this embodiment is similar to the backlight module 100d in FIG. 6. A difference between the two is that the backlight module 100f in this embodiment further includes a second insulation layer 160.

Specifically, referring to FIG. 8, the second insulation layer 160 is disposed on the conductive layer 130a, so that the conductive layer 130a is disposed between the first insulation layer 150 and the second insulation layer 160. In this embodiment, the second insulation layer 160 includes a third region 161 and a fourth region 162. The third region 161 corresponds to the first portion 131 of the conductive layer 130a, and the fourth region 162 corresponds to the second portion 132a of the conductive layer 130a. In the third direction Z, the third region 161 overlaps the first portion 131 of the conductive layer 130a, and the fourth region 162 overlaps the second portion 132a of the conductive layer 130a.

In this embodiment, the third region 161 has a thickness T3, and the fourth region 162 has a thickness T4. The thickness T4 of the fourth region 162 may be, for example, less than the thickness T3 of the third region 161 (i.e., T4<T3), and a sum of the thickness T4 of the fourth region 162 and the thickness T2 of the second region 152 may, for example, be less than a sum of the thickness T3 of the third region 161 and the thickness T1 of the first region 151 (i.e., T4+T2<T3+T1). However, the disclosure is not limited thereto. The thickness T3 is, for example, the thickness of the third region 161 measured along the third direction Z, and the thickness T4 is, for example, the thickness of the fourth region 162 measured along the third direction Z. In this embodiment, the second insulation layer 160 may be a single-layer structure or a multi-layer structure, and a material of the second insulation layer 160 may include an organic material, an inorganic material, or a combination of the foregoing. However, the disclosure is not limited thereto. In this embodiment, the sum of the thickness T1 of the first region 151 of the first insulation layer 150 and the thickness T3 of the third region 161 of the second insulation layer may be, for example, 600 nm to 1000 nm, 1000 nm to 1500 nm, 1500 nm to 2000 nm, etc., and the sum of the thickness T2 of the second region 152 of the first insulation layer 150 and the thickness T4 of the fourth region 162 of the second insulation layer 160 may be, for example, 0 nm to 600 nm. However, the disclosure is not limited thereto. In addition, compared to a situation in which in the manufacturing process of the general backlight module, when the laser is used for the cutting step, it will be absorbed because the laser passes through the insulation layer, resulting in the reduced laser energy or poor cutting, since the thickness T4 of the fourth region 162 of the second insulation layer 160 in this embodiment may be less than the thickness T3 of the third region 161, and the sum of the thickness T4 of the fourth region 162 and the thickness T2 of the second region 152 may be less than the sum of the thickness T3 of the third region 161 and the thickness T1 of the first region 151, the backlight module 100f in this embodiment may reduce the laser absorption during the cutting step of the manufacturing process, thereby reducing the loss of laser energy or improving the cutting yield.

In this embodiment, a manufacturing method of the backlight module 100f further includes the following. The second insulation layer 160 is formed on the conductive layer 130a. A method of forming the second insulation layer 160 may refer to the method of forming the first insulation layer. Therefore, the same details will not be repeated in the following. The third region 161 of the second insulation layer 160 includes a third insulation material and a fourth insulation material, and the fourth region 162 of the second insulation layer 160 includes the second insulation material. Therefore, the thickness of the third region 161 of the second insulation layer 160 is also greater than the thickness of the fourth region 162. The third region 161 may correspond to the first portion 131 of the second conductive layer 130a, and the fourth region 162 may correspond to the second portion 132a of the second conductive layer 130a.

In this embodiment, roughness of a surface 1621 of the fourth region 162 of the second insulation layer 160 after laser cutting may, for example, be greater than roughness of a surface 1611 of the third region 161, but the disclosure is not limited thereto. In another embodiment, the roughness of the side surface 1323a of the second portion 132a of the conductive layer 130a adjacent to the edge 1121 of the peripheral region 112 may be, for example, greater than that of the side surface 1313 of the first portion 131 adjacent to the edge 1121 of the peripheral region 112, but the disclosure is not limited thereto. Roughness of a side surface 1622 of the fourth region 162 of the second insulation layer 160 adjacent to the edge 1121 of the peripheral region 112 may be greater than that of a side surface 1612 of the third region 161 adjacent to the edge 1121 of the peripheral region 112, but the disclosure is not limited thereto.

Based on the above, in the backlight module and the manufacturing method thereof according to the embodiment of the disclosure, since the second portion of the conductive layer has the opening that may overlap the cutting line (or the minimum width of the second portion of the conductive layer may be less than the minimum width of the first portion), the backlight module may reduce the reflection of the laser by reducing the path of the laser passing through the conductive layer during the cutting step of the manufacturing process, thereby reducing the loss of laser energy or improving the cutting yield. In addition, since the second metal layer thickness of the second portion of the conductive layer in this embodiment may be less than the first metal layer thickness of the first portion (or the thickness of the insulation layer corresponding to the second portion may be less than the thickness of the insulation layer corresponding to the first portion), the backlight module may reduce the laser absorption during the cutting step of the manufacturing process, thereby reducing the loss of laser energy or improving the cutting yield.

Lastly, it is to be noted that: the embodiments described above are only used to illustrate the technical solutions of the disclosure, and not to limit the disclosure; although the disclosure is described in detail with reference to the embodiments, those skilled in the art should understand: it is still possible to modify the technical solutions recorded in the embodiments, or to equivalently replace some or all of the technical features; the modifications or replacements do not cause the essence of the corresponding technical solutions to deviate from the scope of the technical solutions of the embodiments.

What is claimed is:

1. A backlight module, comprising:
a substrate comprising a central region and a peripheral region, wherein the peripheral region surrounds the central region;
a light emitting element disposed in the central region; and
a conductive layer disposed in the peripheral region and electrically connected to the light emitting element,
wherein the conductive layer has a first portion and a second portion, the first portion is closer to the light emitting element than the second portion, the first portion has a first metal layer area, the second portion has a second metal layer area, and the first metal layer area is greater than the second metal layer area.

2. The backlight module according to claim 1, further comprising:
a driving circuit, wherein the conductive layer is electrically connected to the light emitting element through the driving circuit.

3. The backlight module according to claim 1, wherein the first portion has a first metal layer thickness, the second portion has a second metal layer thickness, and the second metal layer thickness is less than the first metal layer thickness.

4. The backlight module according to claim 1, further comprising:
a first insulation layer disposed between the substrate and the conductive layer.

5. The backlight module according to claim 4, wherein the first insulation layer comprises a first region and a second region, the first region corresponds to the first portion, the second region corresponds to the second portion, and a thickness of the second region is less than a thickness of the first region.

6. The backlight module according to claim 5, wherein roughness of the second region is greater than roughness of the first region.

7. The backlight module according to claim 4, further comprising:
a second insulation layer, wherein the conductive layer is disposed between the first insulation layer and the second insulation layer.

8. The backlight module according to claim 7, wherein the second insulation layer comprises a third region and a fourth region, the third region corresponds to the first portion, the fourth region corresponds to the second portion, and a thickness of the fourth region is less than a thickness of the third region.

9. The backlight module according to claim 8, wherein roughness of the fourth region is greater than roughness of the third region.

10. The backlight module according to claim 1, wherein roughness of the second portion is greater than roughness of the first portion.

11. The backlight module according to claim 10, wherein roughness of a surface of the second portion away from the substrate is greater than roughness of a surface of the first portion away from the substrate.

12. The backlight module according to claim 10, wherein roughness of a side surface of the second portion adjacent to the peripheral region is greater than roughness of a side surface of the first portion adjacent to the peripheral region.

13. The backlight module according to claim 1, wherein the first portion has a first minimum width, the second portion has a second minimum width, and the second minimum width is less than the first minimum width.

14. The backlight module according to claim 1, wherein the second portion has at least one sub-portion and at least one opening, and the at least one opening exposes a portion of the substrate.

15. The backlight module according to claim 14, wherein the first portion has a first minimum width, the at least one sub-portion has a third minimum width, and the third minimum width is less than the first minimum width.

16. The backlight module according to claim 15, wherein the at least one sub-portion is a plurality of sub-portions, the at least one opening is a plurality of openings, the sub-portions are separated from one another, and the openings separate the sub-portions.

17. The backlight module according to claim 1, wherein a shape of the second portion is comb-like, trapezoidal, or U-shaped.

18. A manufacturing method of a backlight module, comprising:
providing a substrate, wherein the substrate comprises a central region, a peripheral region, and a region to be cut, the peripheral region surrounds the central region, and the region to be cut surrounds the peripheral region;
disposing a light emitting element in the central region;
forming a first conductive layer in the peripheral region and the region to be cut to be electrically connected to the light emitting element; and
through a cutting step, removing the first conductive layer located in the region to be cut to obtain a second conductive layer,
wherein the second conductive layer has a first portion and a second portion, the first portion is closer to the light emitting element than the second portion, the first portion has a first metal layer area, the second portion has a second metal layer area, and the first metal layer area is greater than the second metal layer area.

19. The manufacturing method according to claim 18, further comprising:
forming a first insulation layer between the substrate and the first conductive layer, wherein the first insulation layer comprises a first region and a second region, the first region corresponds to the first portion, the second region corresponds to the second portion, and a thickness of the first region is greater than a thickness of the second region.

20. The manufacturing method according to claim 18, further comprising:
forming a second insulation layer such that the conductive layer is disposed between the first insulation layer and the second insulation layer.
wherein the second insulation layer comprises a third region and a fourth region, the third region corresponds to the first portion, the fourth region corresponds to the second portion, and a thickness of the fourth region is less than a thickness of the third region.
